(19) United States
(12) Patent Application Publication
(10) Pub. No.: US 2012/0085397 A1
(43) Pub. Date: Apr. 12, 2012

(54) SOLAR CELL

(76) Inventors: Choul KIM, Seoul (KR); Kwangsun Ji, Seoul (KR); Kihoon Park, Seoul (KR); Junghoon Choi, Seoul (KR); Youngjoo Eo, Seoul (KR)

(21) Appl. No.: 13/269,375

(22) Filed: Oct. 7, 2011

(30) Foreign Application Priority Data
Oct. 11, 2010 (KR) 10-2010-0098597
Oct. 27, 2010 (KR) 10-2010-0105059

(51) Int. Cl. H01L 31/06

(52) U.S. Cl. 136/255

(57) ABSTRACT

A solar cell includes a first conductivity type crystalline semiconductor substrate, a first amorphous silicon region, a first electrode, and a second electrode. The crystalline semiconductor substrate may include a plurality of pyramidal-shaped projections or a plurality of reverse-pyramidal shape depressions on at least one surface thereof. The first amorphous silicon region may be positioned on the crystalline semiconductor substrate and have a second conductivity type opposite the first conductivity type. The first electrode may be positioned on the first amorphous silicon region, and a second electrode positioned on the substrate. At least one pyramidal-shaped projection or at least one reverse-pyramidal shape depression may include two adjacent inclination surfaces, and a rounded edge portion where the two adjacent inclination surfaces meet.

### CROSS-REFERENCE TO RELATED APPLICATIONS

This application claims priority to and the benefit of Korean Patent Application No. 10-2010-0098597 and Korean Patent Application No. 10-2010-0105059 filed in the Korean Intellectual Property Office on Oct. 11, 2010 and Oct. 27, 2010 respectively, the entire contents of which are incorporated herein by reference.

### BACKGROUND OF THE INVENTION

(a) Field of the Invention

Embodiments of the invention relate to a solar cell.

(b) Description of the Related Art

Lately, alternative energy sources have been receiving greater attention because it has been expected that traditional energy resources such as oil and coal will be depleted. As an up and coming alternative energy source, solar cells are drawing attention. The solar cell is also referred to as a next generation battery that employs a semiconductor element capable of directly converting a solar light energy to an electric energy.

A typical solar cell includes semiconductor units and electrodes. The semiconductor units form a p-n junction because the semiconductor units have different conductivity types such as a p-conductivity type and an n-conductivity type. The electrodes are respectively connected to the semiconductor units each having a different conductivity type.

When light enters a typical solar cell, an electron-hole pair is generated in the semiconductor units. The generated electron-hole pair is separated into an electron and a hole by a photovoltaic effect thereof. The electron moves toward the n-conductivity type semiconductor unit, and the hole moves toward the p-conductivity type semiconductor unit. The electrodes connected to the semiconductor units collect the electron and the hole, respectively. The electrodes are connected through a wire so as to obtain electric power.

### SUMMARY OF THE INVENTION

In accordance with an aspect of the invention, a solar cell includes a first conductivity type crystalline semiconductor substrate, a first amorphous silicon region, a first electrode, and a second electrode. The crystalline semiconductor substrate may include a plurality of pyramidal-shaped projections or a plurality of reverse-pyramidal shape depressions on at least one surface thereof. The first amorphous silicon region may be positioned on the crystalline semiconductor substrate and have a second conductivity type opposite the first conductivity type. The first electrode may be positioned on the first amorphous silicon region, and a second electrode positioned on the substrate. At least one pyramidal-shaped projection or at least one reverse-pyramidal shape depression may include two adjacent inclination surfaces, and a rounded edge portion where the two adjacent inclination surfaces meet.

The at least one pyramidal-shaped projection or the at least one reverse-pyramidal shape depression may further include another inclination surface and a rounded apex portion where the two adjacent inclination surfaces and the another inclination surface meet.

The rounded edge portion and the rounded apex portion may have diameters of about 5 nm to 15 nm, respectively.

Base portions of the plurality of pyramidal-shaped projections may have a width of about 5 μm to 15 μm.

An angle formed by one of the two adjacent inclination surfaces and a base portion of the at least one pyramidal-shaped projection may be equal to or more than about 45° and less than about 54.7°

The solar cell may further include a valley portion between two adjacent pyramidal-shaped projections. The valley portion may have a rounded portion.

The crystalline semiconductor substrate may have an incident surface and a back surface that is opposite the incident surface, and the back surface may lack the plurality of pyramidal-shaped projections or the plurality of the reverse-pyramidal shape depressions.

The crystalline semiconductor substrate may have an incident surface, and the crystalline semiconductor substrate may further include a front passivation region positioned on the incident surface and containing an amorphous silicon material.

The front passivation region may have a uniform thickness at the rounded edge portion or the rounded apex portion.

The crystalline semiconductor substrate may have an incident surface, and the plurality of pyramidal-shaped projections or the plurality of reverse-pyramidal-shape depressions may be on the incident surface. A ratio of a depth with respect to a width in a base of each of the plurality of reverse-pyramidal shape depressions may be 1:1 to 1.5.

A width of a base of each of the plurality of reverse-pyramidal shape depressions may be about 0.5 μm to 10 μm. A depth of each of the plurality of reverse-pyramidal shape depressions may be about 0.5 μm to 15 μm.

A space between bases of two adjacent reverse-pyramidal shape depressions may be equal to or less than 1 μm.

The crystalline semiconductor substrate may have an incident surface and a back surface that is opposite the incident surface, and the first amorphous region may be positioned on the back surface.

The solar cell may further include a second amorphous silicon region positioned on the crystalline semiconductor substrate and having the first conductivity type, and the second amorphous region may be positioned on the back surface.

### BRIEF DESCRIPTION OF THE DRAWINGS

Embodiments of the invention will be described in detail with reference to the following drawings in which like numerals refer to like elements.

FIG. 1 is a partial perspective view of a solar cell in accordance with an embodiment of the invention.

FIG. 2 is a cross section view of the solar cell of FIG. 1 taken along the II-II.

FIG. 3 illustrate a plurality of pyramidal-shaped projections each having a rounded edge portion formed at where adjacent inclination surfaces meet, in accordance with an embodiment of the invention.

FIGS. 4 to 6 are diagrams for describing forming of a rounded portion at an apex portion of a pyramidal shaped projection and an edge of an inclination surface of FIG. 3.

FIGS. 7 to 9 illustrate a method for forming a rounded portion at an edge portion, an apex portion, and a valley portion of a pyramidal shaped projection, in accordance with an embodiment of the invention.

FIGS. 10 and 11 illustrate a solar cell in accordance with another embodiment of the invention.

FIGS. 12A to 12D illustrate a plurality of reverse-pyramidal shaped depressions formed on the crystalline semiconductor substrate shown in FIGS. 10 and 11.

FIG. 13 is a diagram for describing effects provided due to a curved space at a lower apex portion of a reverse-pyramidal shaped depression of FIG. 12.

FIGS. 14 to 17 illustrate a method for forming a curved space at an edge portion ERP of an inclination surface SRP of a lower apex portion VRP of each reverse-pyramidal shaped depression RP.

### DETAILED DESCRIPTION OF THE EMBODIMENTS

In the following detailed description, only certain example embodiments of the invention have been shown and described, simply by way of illustration. As those skilled in the art would realize, the described embodiments may be modified in various different ways, all without departing from the spirit or scope of the invention. Accordingly, the drawings and description are to be regarded as illustrative in nature and not restrictive, and like reference numerals designate like elements throughout the specification.

In the drawings, it will be understood that when each constituent element such as a layer, film, region, or substrate is referred to as being “on” or “under” another element, it can be directly on or under the other element or it can be indirectly on or under the other element. Intervening elements may also be present . Furthermore, a top or a bottom of each constituent element may be described based on a top or a bottom of the drawings. In the drawings, each constituent element may be exaggerated, omitted, or schematically illustrated for better understanding and ease of description. A size of each constituent element may be different from the actual size thereof.

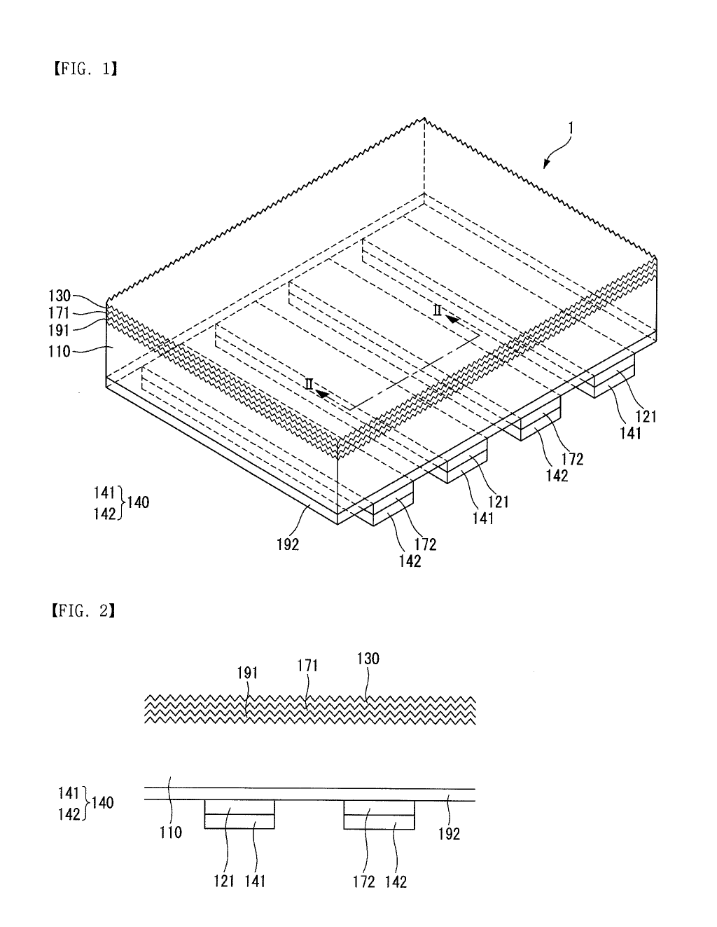

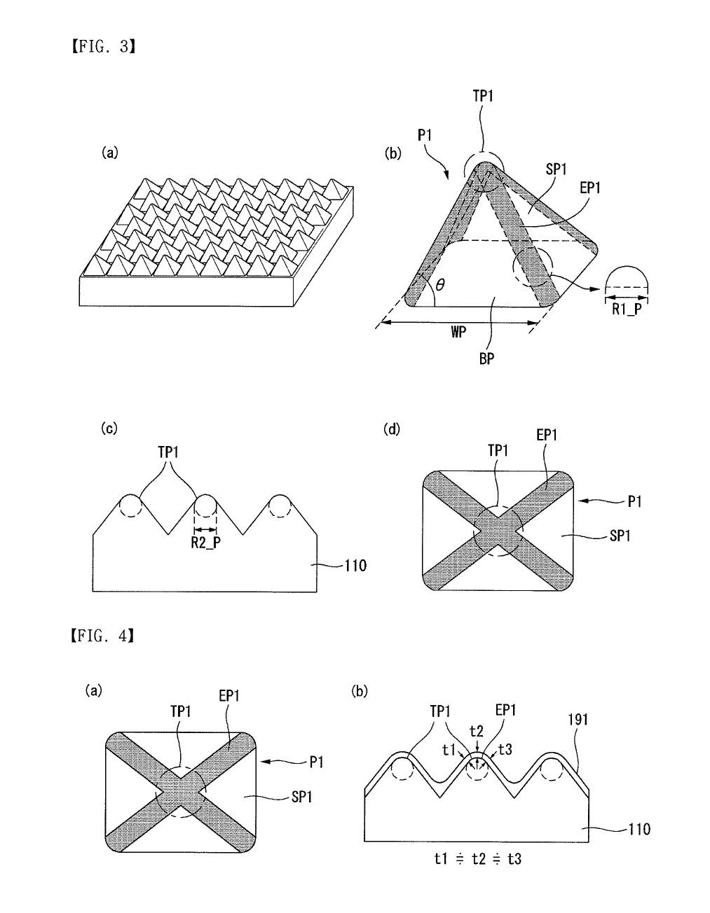

Hereinafter, a solar cell in accordance with an embodiment of the invention will be described with reference to FIGS. 1 and 2.

FIG. 1 is a partial perspective view of a solar cell in accordance with an embodiment of the invention. FIG. 2 is a cross section view of the solar cell of FIG. 1 taken along line II-II.

Referring to FIGS. 1 and 2, the solar cell 1 may include a substrate 110, such as a crystalline semiconductor substrate 110, a front passivation region 191, a front surface field (FSF) region 171, an antireflection region 130, a back passivation region 192, an emitter region 121, a back surface field (BSF) region 172, a plurality of first electrodes 141, and a plurality of second electrodes 142. The front passivation region 191 may be positioned on an incident surface of the crystalline semiconductor substrate 110. The incident surface may be a surface of the crystalline semiconductor substrate 110 where light enters the solar cell 1. Hereinafter, the incident surface may be referred to as a front surface. The front surface field (FSF) region 171 may be positioned on the front passivation region 191. The antireflection region 130 may be positioned on the front surface field (FSF) region 171. The back passivation region 192 may be positioned on the other surface of the crystalline semiconductor substrate 110 where light does not enter. The other surface is opposite to the front surface. The other surface of the crystalline semiconductor substrate 110 may be referred to as a back surface hereinafter. The plurality of emitter regions 121 may be positioned on the back passivation region 192. The plurality of emitter regions 121 may be a first amorphous silicon region. The back surface field (BSF) region 172 may be positioned on the back passivation region 192 and separated from respective emitter region 121. The back surface field (BSF) region 172 may be a second amorphous silicon region. The plurality of first electrodes 141 may be positioned on the plurality of first amorphous silicon regions 121, respectively. The plurality of second electrodes 142 may be positioned on the plurality of second amorphous silicon regions 142, respectively.

The solar cell 1 is illustrated in FIGS. 1 and 2 as including the front surface field (FSF) region 171, the second amorphous silicon regions 172, and the back passivation region 192. However, the front surface field (FSF) region 171, the second amorphous silicon regions 172, and the back passivation region 192 may be omitted in a solar cell in accordance with another embodiment of the invention.

When the front surface field (FSF) region 171, the second amorphous silicon regions 172, and the back passivation region 192 are included in a solar cell, the solar cell may have better photovoltaic efficiency than one that does not include the front surface field (FSF) region 171, the second amorphous silicon regions 172, and the back passivation region 192. Hereinafter, the solar cell 1 will be described as including the front surface field (FSF) region 171, the second amorphous silicon regions 172, and the back passivation region 192.

The first amorphous silicon region 121 may be referred to as the emitter region 121, and the second amorphous silicon region 172 may be referred to as the back surface field (BSF) region 172. Hereinafter, the first amorphous silicon region 121 will be described as the emitter region 121, and the second amorphous silicon region 172 will be described as the back surface field (BSF) region 172.

The crystalline semiconductor substrate 110 may be a crystalline semiconductor substrate formed of first conductivity type silicon, such as n-conductivity type silicon. The silicon may be crystalline silicon such as single crystal silicon or poly crystal silicon. When the crystalline semiconductor substrate 110 contains the n-conductivity type silicon, the crystalline semiconductor substrate 110 may be doped with pentavalent (group V) elements such as phosphorus (P), arsenic (As), and antimony (Sb). Unlike the n-conductivity type crystalline semiconductor substrate 110, the crystalline semiconductor substrate 110 may be a p-conductivity type semiconductor substrate, and be made of other semiconductor material besides silicon. When the crystalline semiconductor substrate 110 has the p-conductivity type, the crystalline semiconductor substrate 110 may be doped with trivalent (group III) elements such as boron (B), gallium (Ga), and indium (In).

The crystalline semiconductor substrate 110 may include a textured incident surface. For convenience and ease of understanding, FIG. 1 illustrates only an edge of the crystalline semiconductor substrate 110 as a textured surface as well as edges of the front passivation region 191, the front surface field (FSF) region 171, and the antireflection region 130. However, an entire front surface of the crystalline semiconductor substrate 110 is a textured surface. Accordingly, entire surfaces of the front passivation region 191, the front surface field (FSF) region 171 and the antireflection region 130 are also textured surfaces.

As described above, the textured surface positioned on the incident surface of the crystalline semiconductor substrate 110 may include a plurality of pyramidal-shaped projections. At least one pyramidal-shaped projection may include two adjacent inclination surfaces and a rounded edge portion where the two adjacent inclination surfaces meet. The rounded edge portion will be described in detail with reference to FIG. 3 below.

Unlike the crystalline semiconductor substrate 110 illustrated in FIGS. 1 and 2, the crystalline semiconductor substrate 110 may have a textured back surface. In this instance, the back passivation region 192, a plurality of emitter regions 121, the back surface field (BSF) region 172, and the first and second electrodes 141, and 142, which are positioned on the back surface of the crystalline semiconductor substrate 110, may also have textured surfaces.

When the back surface of the crystalline semiconductor substrate 110, which is opposite the incident surface, is not a textured surface as illustrated in FIGS. 1 and 2, the back surface may not include a plurality of projections. In this instance, the back passivation region 192, the emitter region 121, and the back surface field (BSF) region 172 may be further uniformly and stably adhered to the crystalline semiconductor substrate 110. Furthermore, in this instance, contact resistance among the emitter region 121, the back surface field (BSF) region 172, and the first and second electrodes 141 and 142 may be reduced.

When the back surface of the crystalline semiconductor substrate 110 does not include a plurality of projections, the back passivation region 192, the plurality of emitter regions 121, and the back surface fields BSF 172 may further be formed at a uniform thickness.

When a textured surface is not formed at the back surface of the crystalline semiconductor substrate 110, textured surfaces may be not formed on the emitter region 121 and the back surface field (BSF) region 172. In this instance, the first and second electrodes 141 and 142 may be further stably attached on the emitter region 121 and the back surface field (BSF) region 172. Accordingly, contact resistance between the emitter region 121 and the back surface field (BSF) region 172 and the first and second electrodes 141 and 142 may be further reduced.

The front passivation region 191 positioned on a front surface of the crystalline semiconductor substrate 110 may include at least one of intrinsic amorphous silicon (a-Si) layer, a silicon nitride layer (SiNx), and a silicon oxide layer (SiOx).

A defect, such as a dangling bond, may exist on a surface of the crystalline semiconductor substrate 110 and in the vicinity thereof. The front passivation region 191 may change such a dangling bond to a stable bond so as to reduce extinction of electric charges that move toward the surface of the crystalline semiconductor substrate 110. That is, the front passivation region 191 may perform a passivation function so as to reduce an amount of electric charge lost on the surface of the crystalline semiconductor substrate 110 and in the vicinity thereof.

Generally, the defect is mainly generated on the surface of the crystalline semiconductor substrate 110 and in the vicinity thereof. Since the front passivation region 191 directly contacts the surface of the crystalline semiconductor substrate 110, the passivation function may be further improved and an amount of electric charge loss may be further decreased.

In accordance with an embodiment of the invention, a thickness of the front passivation region 191 may be about 1 nm to about 30 nm.

When the thickness of the front passivation region 191 is thicker than about 1 nm, the front passivation region 191 may be uniformly coated on the front surface of the crystalline semiconductor substrate 110 so as to properly perform the passivation function. When the thickness of the front passivation region 191 is thinner than about 30 nm, an amount of light absorbed in the front passivation region 191 may be reduced so as to increase an amount of light incident in the crystalline semiconductor substrate 110.

The front surface field (FSF) region 171, positioned on the front passivation region 191, may be an impurity region containing impurities identical to that of the crystalline semiconductor substrate 110, such as n-type impurity, at a higher concentration than that of the crystalline semiconductor substrate 110. In accordance with an embodiment of the invention, the impurity doping concentration of the front surface field (FSF) region 171 may be about 10¹⁰ to 10²¹ atoms/cm³.

In accordance with an embodiment of the invention, the front surface field (FSF) region 171 may contain at least one of amorphous silicon oxide (a-SiOx) and amorphous silicon carbide (a-SiC).

An electric potential barrier may be formed due to an impurity concentration difference between the crystalline semiconductor substrate 110 and the front surface field (FSF) region 171. The electric potential barrier has electric field effect that prevents electric charges, for example, holes, from moving toward the front surface of the crystalline semiconductor substrate 110.

Accordingly, the front surface field (FSF) region 171 may provide a front surface field (FSF) effect. The FSF effect may redirect holes moving toward the front surface back toward the back surface of the crystalline semiconductor substrate 110 by the electric potential barrier. The FSF effect may increase an amount of output electric charges to an external device and reduce an amount of electric charge loss caused by recombination or defect generated at the front surface of the crystalline semiconductor substrate 110.

An energy band gap between the amorphous silicon oxide (a-SiOx) and the amorphous silicon carbide (a-SiC) is about 2.1 and about 2.8. It is wider than that of amorphous silicon, which is about 1.7 to 1.9. Therefore, when the front surface field (FSF) region 171 is formed of the amorphous silicon oxide (a-SiOx) or the amorphous silicon carbide (a-SiC), a wavelength region of light absorbed into the front surface field (FSF) region 171 is reduced. Accordingly, an amount of light absorbed into the front surface field (FSF) region 171 is also reduced, and an amount of light incident to the crystalline semiconductor substrate 110 is further increased.

In accordance with an embodiment of the invention, the front surface field (FSF) region 171 may have an impurity doping concentration that is continuously or discontinuously changed along a thickness direction thereof within an range from about 10¹⁰ to about 10²¹ atoms/cm³. Or otherwise, the front surface field (FSF) region 171 may have a uniform impurity doping concentration within an range from about 10¹⁶ to about 10²¹ atoms/cm³.

When the impurity doping concentration of the front surface field (FSF) region 171 changes along the thickness direction within a range of about 10¹⁰ to about 10²¹ atoms/cm³, a certain part of the front surface field (FSF) region 171 may perform a passivation function like the front passivation region 191.

In this instance, the impurity doping concentration of the front surface field (FSF) region 171 changes from a part of the front passivation region 191, which contacts the front surface field (FSF) region 171, to another part of the front passivation region 191, which contacts the antireflection region 130.

Accordingly, the impurity doping concentration of the FSF region 171 may be decreased in portions of the FSF region 171 that approaches (or are located closer to) the front passivation region 191. On the contrary, the impurity doping concentration of the FSF region 171 may be increased in portions of the FSF region 171 approaches (or are located closer to) the antireflection region 130. The part contacting the front passivation region 191 is a minimum doping concentration part having a minimum doping concentration in the front surface field (FSF) region 171. This part may have a shortest distance from the surface of the crystalline semiconductor substrate 110 and the front surface field (FSF) region 171. The part contacting the antireflection region 130 is a maximum doping concentration part having the maximum doping concentration with the FSF region 171. This part may have a shortest distance from the surface of the crystalline semiconductor substrate 110 to the antireflection region 130. Two shortest distances may be measured from the same part of the crystalline semiconductor substrate 110.

Accordingly, the minimum doping concentration part may have about 10¹⁰ atoms/cm³, and the maximum doping concentration part may have about 10²¹ atoms/cm³.

In this instance, the front surface field (FSF) region 171 should perform a passivation function as well as a front surface electric field effect. Accordingly, the front surface field (FSF) region 171 needs to be thicker than a layer performing only the front surface field function, and the front passivation region 191 needs to be thinner than a layer performing only the front surface field function. In this instance, the front passivation region 191 may have a thickness of about 1 to about 10 nm, and the front surface field (FSF) region 171 may have a thickness of about 3 nm to about 30 nm.

When the thickness of the front passivation region 191 is thicker than about 1 nm, the front passivation region 191 may be uniformly coated on the back surface of the crystalline semiconductor substrate 110. Accordingly, a better passivation efficiency will be obtained. When the thickness of the front passivation region 191 is thinner than about 10 nm, an amount of light entering the crystalline semiconductor substrate 110 may be further increased because a passivation function is performed without the front passivation region 191 absorbing light.

When the thickness of the front surface field (FSF) region 171 is thicker than about 3 nm, the front surface field (FSF) region 171 may generate FSF strength that can stably perform a FSF function although a part of the front surface field (FSF) region 171 performs the passivation function. Furthermore, the front surface field (FSF) region 171 may generate a normal front surface field effect regardless of an adverse influence of the front passivation region 191. The front passivation region 191 adversely influences the FSF strength relative to the crystalline semiconductor substrate 110 because the front passivation region 191 is positioned between the crystalline semiconductor substrate 110 and the front surface field (FSF) region 171. When the thickness of the front surface field (FSF) region 171 is less than about 30 nm, the front surface field (FSF) region 171 may perform a front surface field function without absorbing the light. Accordingly, an amount of light entering the crystalline semiconductor substrate 110 may be further increased.

When the front surface field (FSF) region 171 has uniform impurity doping concentration as an alternative example, the impurity concentration of the front surface field (FSF) region 171 may be uniform regardless of a thickness variation thereof.

Since the front surface field (FSF) region 171 may mainly (or primarily) perform the front surface field function for generating the front surface field effect when the front surface field (FSF) region 171 has uniform impurity doping concentration, the front surface field (FSF) region 171 need to have an impurity concentration that can properly perform the front surface field function using an impurity concentration difference between that of the front surface field (FSF) region 171 and the crystalline semiconductor substrate 110. Accordingly, when the front surface field (FSF) region 171 mainly performs the front surface field function, the front surface field (FSF) region 171 may have an impurity concentration higher than that when a part of the front surface field (FSF) region 171 performs the passivation function. Furthermore, the front surface field (FSF) region 171 may have an impurity doping concentration higher than that of the crystalline semiconductor substrate 110. In accordance with an embodiment of the invention, the front surface field (FSF) region 171 may have uniform impurity doping concentration in a range of about 10¹⁶ to 10²¹ atoms/cm³.

Since the front passivation region 191 mainly (primarily) performs the front surface field function rather than the passivation function, the front passivation region 191 positioned under the front surface field (FSF) region 171 may have a further thicker thickness compared to that of the front passivation region 191 positioned under a front surface field (FSF) region 171 having a part performing not only the front surface field function but also the passivation function. In this instance, the front surface field (FSF) region 171 may have a further thinner thickness because the front surface field (FSF) region 171 only performs the front surface field function. In this instance, the front passivation region 191 may have a thickness of about 2 nm to about 20 nm, and the front surface field (FSF) region 171 may have a thickness of about 1 nm to about 20 nm.

When the thickness of the front passivation region 191 is thicker than about 2 nm, the front passivation region 191 may stably eliminate defects that are generated on the surface of the crystalline semiconductor substrate 110 or around the surface. Accordingly, the front passivation region 191 may perform the passivation function more properly or adequately. When the thickness of the front passivation region 191 is thinner than about 20 nm, the front passivation region 191 may perform the passivation function without absorbing light. Therefore, an amount of light entering the crystalline semiconductor substrate 110 may be further increased.

As described above, the front passivation region 191 may adversely influence the front surface field strength relative to the crystalline semiconductor substrate 110 because the front passivation regions 191 is positioned between the crystalline semiconductor substrate 110 and the front surface field (FSF) region 171. When the thickness of the front surface field (FSF) region 171 is thicker than about 1 nm, the front surface field (FSF) region 171 may form a normal front surface field strength regardless of the adverse influence of the front passivation region 191. Accordingly, the front surface field (FSF) region 171 may stably perform the front surface field function. When the thickness of the front surface field (FSF) region 171 is thinner than about 20 nm, the front surface field (FSF) region 171 performs the front surface field function without absorbing light. Accordingly, the amount of light entering the crystalline semiconductor substrate 110 may be further increased.

The antireflection region 130 may be positioned on the front surface field (FSF) region 171. The antireflection region 130 may reduce reflectivity of light entering to the solar cell 1 and increase selectivity of a certain wavelength region so as to increase efficiency of the solar cell 1. Such an antireflection region 130 may be formed of a silicon nitride layer (SiNx) or a silicon oxide (SiOx). In accordance with an embodiment of the invention, the antireflection region 130 may be a single layer structure. However, the antireflection region 130 may have a multilayer structure in another embodiment of the invention. Furthermore, the antireflection region 130 may be omitted in yet another embodiment of the invention.

The back passivation region 192 may be positioned on the back surface of the crystalline semiconductor substrate 110. The back passivation region 192 may perform a passivation function like the front passivation region 191 so as to reduce loss of electric charges moving towards the back surface of the crystalline semiconductor substrate 110, which may be caused by defects.

The back passivation region 192 may contain amorphous silicon like the front passivation region 191.

The back passivation region 192 may have a thickness that can pass electric charges toward the plurality of back surface fields (BSF) 172 and the plurality of emitter regions 121. In accordance with an embodiment of the invention, the thickness of the back passivation region 192 may be about 1 to about 10 nm.

When the thickness of the back passivation region 192 is thicker than about 1 nm, the back passivation region 192 may be uniformly coated on the back surface of the crystalline semiconductor substrate 110. Accordingly, the back passivation region 192 may provide a better passivation effect. When the thickness of the back passivation region 192 is thinner than about 10 nm, the amount of light absorbed into the back passivation region 192 may be reduced. Accordingly, an amount of light re-entering to the crystalline semiconductor substrate 110 may be increased.

The plurality of back surface field (BSF) regions 172 may be doped with the same conductivity type impurity of the crystalline semiconductor substrate 110 at a higher doping concentration than that of the crystalline semiconductor substrate 110. For example, the plurality of back surface field (BSF) regions 172 may be n+ type impurity regions.

The plurality of back surface fields (BSF) regions 172 may be positioned on the back passivation region 92 at a predetermined gap. The plurality of back surface fields (BSF) regions 172 are extended in parallel with each other in a predetermined direction. In accordance with an embodiment of the invention, the plurality of back surface field (BSF) regions 172 may be formed of a non-crystalline semiconductor such as amorphous silicon (a-Si).

Like the front surface field (FSF) region 171, the back surface field (BSF) region 172 may form an electric potential barrier due to a difference of impurity concentrations of the crystalline semiconductor substrate 110 and the back surface field (BSF) region 172. The electric potential barrier may disturb holes moving toward the back surface field (BSF) region 172, which is a moving direction of electrons. On the contrary, the electric potential barrier may facilitate electric charges, for example electrons, in moving toward the back surface field (BSF) region 172. Accordingly, the back surface field (BSF) region 172 may reduce an amount of electric charge loss which might be caused by electron and hole recombination at the back surface field (BSF) regions 172 or in the vicinity thereof and the first and second electrodes 141 and 142. Furthermore, the back surface field (BSF) region 172 may accelerate electron movement so as to increase an amount of electrons moving toward the back surface field (BSF) region 172.

Each one of the back surface field (BSF) regions 172 may have a thickness of about 10 nm to about 25 nm. When the thickness of the back surface field (BSF) region 172 is thicker than about 10 nm, the electric potential barrier may be further properly or adequately formed. Accordingly, the loss of electric charges may be further reduced. When the thickness of the back surface field (BSF) region 172 is thinner than about 25 nm, the back surface field (BSF) region 172 may reduce an amount of light absorption so as to increase an amount of light re-entering back into the crystalline semiconductor substrate 110.

The plurality of emitter regions 121 may be positioned on the back surface of the crystalline semiconductor substrate 110 and separated from the plurality of the back surface field (BSF) regions 172. The plurality of emitter regions 121 may extend in parallel with the back surface field (BSF) regions 172.

As illustrated in FIGS. 1 and 2, the back surface field (BSF) regions 172 and the emitter regions 121 may be alternately positioned on the crystalline semiconductor substrate 110.

Each emitter region 121 may be formed on the back surface of the crystalline semiconductor substrate 110. The emitter region 121 may have a second conductivity type which is opposite to the conductivity type of the crystalline semiconductor substrate 110. The second conductivity type may be a p-conductivity type. The emitter region 121 may contain amorphous silicon, which is different from the crystalline semiconductor substrate 110. Therefore, the emitter regions 121 may form a hetero junction with the crystalline semiconductor substrate 110 as well as a p-n junction with the crystalline semiconductor substrate 110.

A built-in potential difference may be generated by a p-n junction formed between the crystalline semiconductor substrate 110 and the plurality of emitter regions 121. Due to the built-in potential difference, an electron-hole pair may be separated to an electron and a hole when the electron-hole pair is generated by light entering the crystalline semiconductor substrate 110. The electron may move towards an n-type semiconductor, and the hole may move toward a p-type semiconductor. For example, when the crystalline semiconductor substrate 110 is an n-type and the plurality of the emitter regions 121 are a p-type, the separated hole passes through the back passivation region 192 and moves towards each emitter region 121, and the separated electron passes through the back passivation region 192 and moves toward the plurality of back surface field (BSF) regions 172 having the impurity concentration higher than that of the crystalline semiconductor substrate 110.

Since each emitter region 121 forms a p-n junction with the crystalline semiconductor substrate 110, the emitter region 121 may have an n-conductivity type when the crystalline semiconductor substrate 110 has a p-conductivity type. In this instance, the separated electron moves toward the emitter region 121 passing through the back passivation region 192, and the separated hole moves toward the plurality of back surface fields (BSF) 172 through the back passivation region 192.

When the plurality of emitter regions 121 have the p-conductivity type, the emitter region 121 may be doped with a trivalent (group III) element impurity. When the plurality of emitter regions 121 have an n-conductivity type, the emitter region 121 may be doped with a pentavalent (group V) element impurity.

The plurality of emitter regions 121 may perform a passivation function with the back passivation region 192. In this instance, the passivation function of the plurality of emitter regions 121 may reduce an amount of electric charge loss at the back surface of the crystalline semiconductor substrate 110 due to the defects. Accordingly, the efficiency of the solar cell 1 may be improved.

Each one of emitter regions 121 may have a thickness of about 5 nm to about 15 nm. When the thickness of the emitter region 121 is thicker than about 5 nm, a p-n junction may further be properly or adequately formed. When the thickness of the emitter region 121 is thinner than about 15 nm, the emitter regions 121 may reduce an amount of light absorption so as to increase an amount of light re-entering back into the crystalline semiconductor substrate 110.

In accordance with an embodiment of the invention, the back passivation region 192 may be positioned under the plurality of emitter regions 121 and the plurality of back surface field (BSF) regions 172, and may be formed of intrinsic semiconductor such as intrinsic amorphous silicon (a-Si) that contains almost no impurity or no impurity. Such a back passivation region 192 may reduce a crystallization phenomenon when the plurality of emitter regions 121 and the back surface field (BSF) regions 172 are formed as compared to when a plurality of emitter regions 121 and a plurality of back surface fields (BSF) 172 are formed directly on the crystalline semiconductor substrate 110 without the back passivat ion region 192. Accordingly, the characteristics of the plurality of emitter regions 121 and the plurality of back surface field (BSF) regions 172 formed on the intrinsic silicon may be improved.

As described above, the plurality of first electrodes 141 may be formed on the plurality of emitter regions 121. The plurality of first electrodes 141 may extend along the plurality of emitter regions 121 and be electrically connected to the plurality of emitter regions 121.

The plurality of first electrodes 141 on the plurality of emitter regions 121 may extend along the plurality of emitter regions 121 and may be physically and electrically connected to the plurality of emitter regions 121.

Each first electrode 141 may collect electric charges such as holes moving toward a corresponding emitter region 121.

A plurality of second electrodes 142 may be positioned on the plurality of back surface field (BSF) regions 172. The plurality of second electrodes 142 may extend along the plurality of back surface fields (BSF) 172 and may be electrically and physically connected to the plurality of back surface fields (BSF) 172.

Each one of the second electrodes 142 may collect electric charges such as electrons moving towards a corresponding back surface field 172.

As illustrated in FIGS. 1 and 2, the first and second electrodes 141 and 142 may have different planar shapes compared to those of the emitter region 121 and the back surface field (BSF) region 172 positioned under the first and second electrodes 141 and 142. The first and second electrodes 141 and 142 may have the same planar shape in accordance with another embodiment of the invention. A contact resistance may be reduced as a contact area between the first and second electrodes 141 and 142 and the emitter region 121 and the back surface field (BSF) region 172 increases. The reduction of the contact resistance may increase an efficiency of transmitting the electric charges toward the first and second electrodes 141 and 142.

The plurality of first and second electrodes 141 and 142 may be formed of a conductive material selected from the group consisting of nickel (Ni), copper (Cu), silver (Ag), aluminum (Al), tin (Sn), zinc (Zn), indium (In), titanium (Ti), gold (Au) and the combination thereof. The embodiments of invention, however, are not limited thereto. The plurality of first and second electrodes 141 and 142 may be formed of another conductive material. When the plurality of first and second electrodes 141 and 142 are formed of a metal material, the plurality of first and second electrodes 141 and 142 reflect light passing through the crystalline semiconductor substrate 110 toward the crystalline semiconductor substrate 110.

In accordance with an embodiment of the invention, the solar cell 1 may include the plurality of first and second electrodes 141 and 142 positioned on the back surface of the crystalline semiconductor substrate 110 where light is not incident thereto. The plurality of emitter regions 121 may be formed of a different type of semiconductor compared to that of the crystalline semiconductor substrate 110 as illustrated above. Such a solar cell may perform the following operations.

When light is radiated to the solar cell 1, the light enters to the crystalline semiconductor substrate 110 after sequentially passing through the antireflection region 130, the front surface field (FSF) region 171 and the front passivation region 191. The crystalline semiconductor substrate 110 may generate electron-hole pairs due to the light energy. Since the crystalline semiconductor substrate 110 has a textured surface, light incidence and light reflection are performed on the textured surface of the crystalline semiconductor substrate 110. Accordingly, the light reflectivity of the front surface of the crystalline semiconductor substrate 110 is reduced and a light absorbing rate thereof is increased. As a result, the efficiency of the solar cell 1 becomes improved. Furthermore, the antireflection region 130 may reduce reflection loss of light when light enters the crystalline semiconductor substrate 110 so as to further increase an amount of light entering the crystalline semiconductor substrate 110.

The electron-hole pairs are separated by a p-n junction between the crystalline semiconductor substrate 110 and the emitter region 121. The hole moves toward to the emitter region 121 having a p-conductivity type, and the electron moves forward the back surface field (BSF) region 172 having an n-conductivity type. Accordingly, the first and second electrodes 141 and 142 collect the holes and the electrons, respectively. When the first electrode 141 and the second electrode 142 are connected through a conductive wire, current flows through the conductive wire and such a current may be used by an external device.

Since the passivation regions 192 and 191 are positioned on the front surface of the crystalline semiconductor substrate 110 as well as the back surface of the crystalline semiconductor substrate 110, the passivation regions 192 and 191 reduce loss of electric charges which may be reduced or extinguished by defects that may exist on the front and back surfaces of the crystalline semiconductor substrate 110. Since the back passivation region 192 and the front passivation region 191 directly contact the surface of the crystalline semiconductor substrate 110 where defects frequently occur, the passivation effect may be further improved.

Furthermore, the electric fields 171 and 172 positioned on the front and back surfaces of the crystalline semiconductor substrate 110 further reduce loss of electric charges so as to further improve the efficiency of the solar cell 1.

As described above, a plurality of pyramidal-shaped projections are formed on the incident surface of the crystalline semiconductor substrate 110. Each pyramidal-shaped projection includes a rounded edge portion formed where two adjacent inclination surfaces meet. Such a rounded edge portion will be described in greater detail, hereinafter.

As described above, and with reference to FIG. 3, the rounded edge portion (EP1) may be formed where the two adjacent inclination surfaces (SP1) meet in the pyramidal shaped projection. Due to a rounded portion, the front passivation region 191 and the front surface field (FSF) region 171 may be further uniformly formed at the rounded edge portion (EP1) on the incident surface of the crystalline semiconductor substrate 110. Accordingly, the rounded edge portion may further improve the passivation effect that electric charges for example electrons are eliminated by dangling bond at the incident surface of the crystalline semiconductor substrate 110. The round edge portion may further improve an electric field effect that prevents loss of electric charge which is caused by electron and hole recombination.

The passivation effect and the electric field effect of the front passivation region 191 and the front surface field (FSF) region 171 may be further improved at in the vicinity of the incident surface of the crystalline semiconductor substrate 110 so as to further improve photoelectric efficiency of the solar cell.

FIG. 3 illustrate a plurality of pyramidal-shaped projections each having a rounded edge portion formed at where adjacent inclination surfaces meet, in accordance with an embodiment of the invention.

A diagram (a) of FIG. 3 illustrates a plurality of pyramidal shaped projections P1 formed on the incident surface of the crystalline semiconductor substrate 110. A diagram (b) of FIG. 3 illustrates a 3-D shape (or a perspective view) of each pyramidal shaped projection P1. A diagram (c) of FIG. 3 is a side view of a cross section of the pyramidal shaped projections. A diagram (d) of FIG. 3 is a top view of a pyramidal shaped projection.

As illustrated in the diagram (a) of FIG. 3, the crystalline semiconductor substrate 110 includes a plurality of projections on the incident surface. The incident surface is the front surface of the crystalline semiconductor substrate 110 as described above. The projections may be formed by texturing. Furthermore, a plurality of projections are not formed on the back surface of the crystalline semiconductor substrate 110 which is opposite to the incident surface.

As illustrated in the diagram (b) of FIG. 3, the pyramidal shaped projection P1 includes a rounded edge portion EP1 formed where adjacent two inclination surfaces SP1 meet.

As illustrated in the diagrams (b) and (c) of FIG. 3, the projection may include a rounded apex portion TP1 where the two adjacent inclination surfaces and another inclination surface meet.

As described above, the rounded edge portion EP1 and the rounded apex portion TP1 of the protrusions have a rounded portion. Therefore, the front passivation region 191 and the front surface field (FSF) region 171, which are formed on the incident surface of the crystalline semiconductor substrate 110, can be further uniformly formed on the rounded edge portion EP1 and the rounded apex portion TP1 of the inclination surface SP1.

Diameters R1_P and R2_P of the rounded edge portion EP1 and the rounded apex portion TP1 may be greater than about 5 nm and smaller than 15 nm.

A diameter R1_P of a rounded portion may be greater than about 5 nm in order to uniformly form the front passivation region 191 and the front surface field (FSF) region 171 on the rounded edge portion EP1 and the rounded apex portion TP1 of the inclination surface SP1.

The diameters R1_P and R2_P of the rounded portion may be smaller than 15 nm in order to minimize reflectivity of incident light. That is, when the diameters R1_P and R2_P of the rounded portion are greater than 15 nm, uniformity of the front passivation region 191 and the front surface field (FSF) region 171 formed on the protrusions will be further improved. However, light reflectivity may be further increased.

A width WP of a base BP of the pyramidal shaped protrusion P1 may be greater than about 5 μm and smaller than about 15 μm. The size of the pyramidal shaped protrusion P1 becomes greater as the width WP of the base BP increases due to the characteristics of the crystalline silicon. The size of the pyramidal shape P1 may become smaller as the width WP of the base BP decreases.

Therefore, the size of the pyramidal shaped protrusion P1 may be optimally obtained by controlling the width WP of the base BP to be greater than about 5 μm and smaller than about 15 μm. Accordingly, an optimal light path may be obtained for incident light so as to improve photoelectric efficiency. That is, the incident light enters and reflects several times by the inclination surfaces SP1 of the plurality of pyramidal shaped projections P1. As described above, a path of incident light may become extended so as to increase an amount of light entering to the crystalline semiconductor substrate 110. Accordingly, the photoelectric efficiency becomes improved.

As illustrated in the diagram (b) of FIG. 3, an angle θ formed by the inclination surface SP1 and the base BP of the pyramidal shaped projection P1 may be greater than about 45° and smaller than about 54.7°.

When the surface of the crystalline semiconductor substrate 110 is processed using a typical texturing method, an angle θ of about 54.7° may be formed by the inclination surface SP1 and the base BP of the pyramidal shaped projection P1.

In accordance with an embodiment of the invention, isotropic etching may be preformed after performing anisotropic etching as a typical texturing method. By further performing the isotropic etching, the angle θ between the inclination surface SP1 and the base surface BP of the pyramidal shaped projection P1 may become smaller than about 54.7°.

In accordance with an embodiment of the invention, an angle between the inclination surface SP1 and the base surface BP may be formed to be greater than about 45° in order to obtain a minimized gradient of the inclination surface SP1 of the pyramidal shaped projection P1 so as to minimize light reflectivity at the incident surface of the crystalline semiconductor substrate 110. In accordance with an embodiment of the invention, an angle between the inclination surface SP1 and the base surface BP may be formed smaller than about 54.7° in order to form the further gradual inclination surface SP1 of the pyramidal shaped projection P1 so as to further uniformly form the front passivation region 191 and the front surface field (FSF) region 171 on the pyramidal shaped protrusions.

FIGS. 4 to 6 are diagrams for describing forming of a rounded portion at an apex portion of a pyramidal shaped projection and an edge of an inclination surface of FIG. 3.

As illustrated in a diagram (a) of FIG. 4, the edge portion EP1 and the apex portion TP1 of the pyramidal shaped projection P1 have a rounded portion. In this instance, the front passivation region 191 formed on the pyramidal shaped projection P1 using a vapor deposition method is uniformly formed on the edge portion EP1 of the inclination surface SP1 and the apex portion TP1 of the pyramidal shaped projection P1 as illustrated in a diagram (b) of FIG. 4.

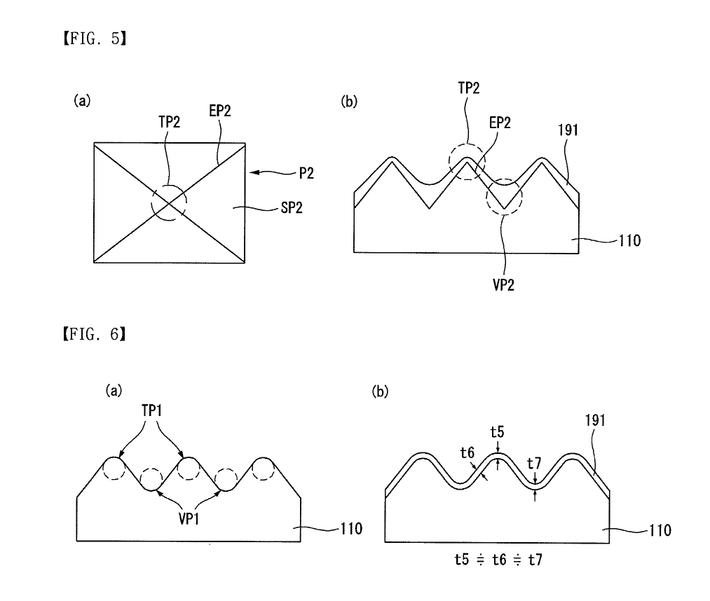

A diagram (a) of FIG. 5 illustrates an edge portion EP2 and an apex portion TP1 of a pyramidal shaped projection P2 not having a rounded portion. In this instance, a front passivation region 191 may be not uniformly formed on the edge portion EP1 of the inclination surface SP1 and the apex portion TP1 of the pyramidal shaped projection P1 as illustrated in a diagram (b) of FIG. 5. For example, thickness of the front passivation region 191 may vary depending on location.

When the front passivation region 191 is not uniformly formed on the front surface of the crystalline semiconductor substrate 110 because a rounded portion is not formed on the edge portion EP2 and the apex portion TP2 of the pyramidal shaped projection P2, the passivation effect may be comparatively reduced at the edge portion EP2 and the apex portion TP2 of the pyramidal shaped projection P2.

In order to generate the passivation effect properly at the front passivation region 191, the front passivation region 191 should be formed to be thicker than a minimum thickness requirement. When the edge portion EP2 or the apex portion TP2 are formed to have a sharp angle, an minimum thickness of the front passivation region 191 cannot be obtained at the edge portion EP2 or the apex portion TP2. Accordingly, the passivation effect may be deteriorated.

Due to such deterioration of the passivation effect, more electric charges may become extinct at the edge portion EP2 and the apex portion TP2. Furthermore, when the front surface field (FSF) region 171 is formed on the front passivation region 191 as illustrated in FIGS. 1 and 2, the electric field effect may not be uniformly generated. Accordingly, there is a large probability that electrons and holes may be recombined at the edge portion EP2 and the apex portion TP2 of the pyramidal shaped projection P2.

In order to overcome such a disadvantage, a front passivation region 191 may be deposited to be comparatively thicker on the pyramidal shaped projection in order to obtain proper passivation effect at the edge portion EP2 and the apex portion TP2 of the pyramidal shaped projection P2. However, in this instance, the front passivation region 191 may be excessively thick at a valley portion VP2 between adjacent pyramidal shaped projections P2.

When the front passivation region 191 is excessively thick at the valley portion between adjacent pyramidal shaped projections as described above, an amount of light absorbed into the front passivation region 191 at the valley portion VP2 may become increased. Accordingly, an amount of light absorbed into the crystalline semiconductor substrate 110 may become decreased.

When the amount of light absorbed into the valley portion VP2 of the crystalline semiconductor substrate 110 becomes reduced, the photoelectric effect of the solar cell may be reduced too.

When the rounded portion is formed at the edge portion EP1 of the inclination surface SP1 and the apex portion TP1 of the pyramidal shaped projection P1, the front passivation region 191 will not be excessively thick at a valley portion VP1 between adjacent pyramidal shaped projections. The front passivation region 191 may be uniformly formed on the rounded edge portion EP1 and the rounded apex portion TP1 of the pyramidal shaped projection P1. Therefore, the passivation effect and the electric field effect may be uniformly generated so as to further improve the photoelectric effect of the solar cell.

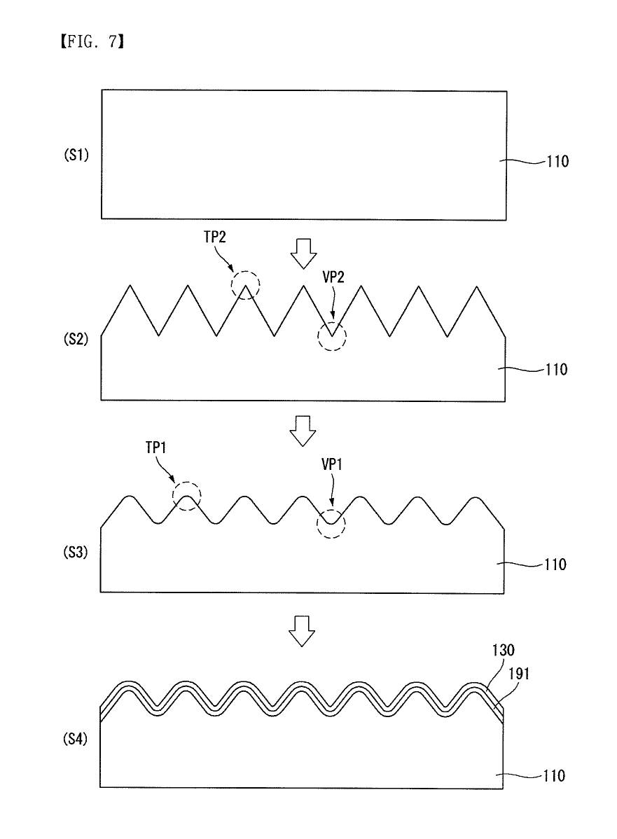

The rounded portions were described as being formed on the apex portion TP1 and the edge portion EP1 of the pyramidal shaped projection P1 in accordance with an embodiment of the invention. However, the rounded portion can be formed at a valley portion VP1 between adjacent pyramidal shaped projection P1 as well as the apex portion TP1 and the edge portion EP1 of the inclination surface SP1, as illustrated in a diagram (a) of FIG. 6.

In this instance, the front passivation region 191 may be uniformly formed at the valley portion VP1 of the pyramidal shaped projection P1 as well as the apex portion TP1 of the pyramidal shaped projection P1 and the edge portion EP1 of the inclination surface SP1. As shown in diagram (b) of FIG. 6, the front passivation region 191 has about the same thicknesses t5, t6 and t7 at different locations. Therefore, the photoelectric effect of the solar cell may be further improved.

Hereinafter, a method for forming a rounded portion at a valley portion VP1 of a plurality of pyramidal shaped projections P1, as well as an edge portion EP1 of an inclination surface SP1 and an apex portion TP1 of a pyramidal shaped projection P1 as shown in FIG. 6.

FIGS. 7 to 9 illustrate a method for forming a rounded portion at an edge portion, an apex portion, and a valley portion of a pyramidal shaped projection, in accordance with an embodiment of the invention.

Referring to FIG. 7, at operation S1, a crystalline semiconductor substrate 110 may be prepared, and one surface of the crystalline semiconductor substrate 110 may be etched using an anisotropic etch. For example, wet etching may be performed as the anisotropic etch. As a result of the anisotropic etching, the one surface of the crystalline semiconductor substrate 110 may be textured, and a plurality of projections may be formed on the textured surface of the crystalline semiconductor substrate 110 at operation S2.

When the wet etching is performed, an etching solution and an etching duration may vary or may be determined through various methods.

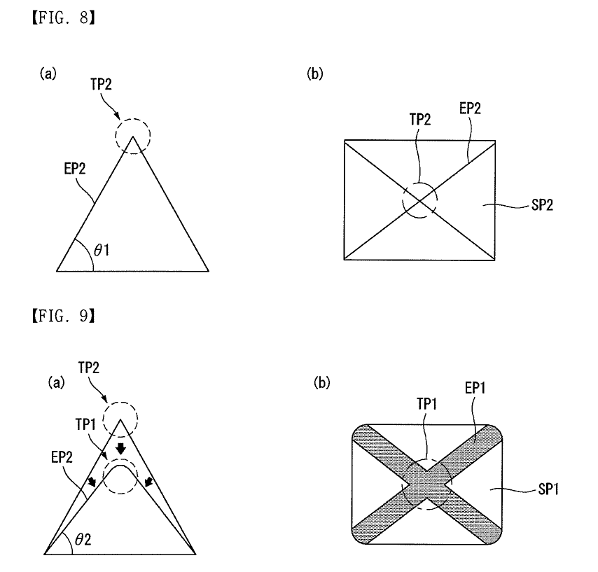

An angle θ1 formed by an inclination surface SP2 and a base BP of the projection may be fixed at about 54.7° due to characteristics of the crystalline semiconductor substrate 110 as illustrated in a diagram (a) of FIG. 8. The edge portion EP2 of the inclination surface of the projection may be formed to have a sharp tip without a rounded portion as illustrated a diagram (b) of FIG. 8.

After the operation S2, isotropic etching is additionally performed at the one surface of the crystalline semiconductor substrate 110 where the anisotropic etching was performed. For example, the isotropic etching or wet etching may be performed, and an etching solution or etching duration may vary or may be determined through various methods.

When the isotropic etching is performed as shown in operation S3, the edge portion EP2, the apex portion TP2, and the valley portion VP2 of the pyramidal shaped projection P2 may be gradually etched. The height of the apex portion TP2 of the pyramidal shaped projection P2 becomes gradually reduced, and angle formed between the inclination surface SP1 and the base surface BP of the pyramidal shaped projection may become smaller than about 54.7°. The angle between the inclination surface SP1 and the base BP may be controlled to be greater than about 45° and smaller than about 54.7° by controlling etching duration of the isotropic etching.

By the anisotropic etching, a rounded portion may be formed at the apex portion TP1 and the edge portion EP1, as illustrated diagrams (a) and (b) of FIG. 9. Furthermore, a valley portion VP1 between two adjacent pyramidal shaped projections P1 may also have a rounded portion at operation S4 as illustrated in FIG. 7.

A diameter R1_P of the rounded portion of the apex portion TP1 of the pyramidal shaped projection P1 and the edge portion EP1 of the inclination surface SP1 may be controlled to be greater than about 5 nm and smaller than about 15 nm by controlling the etching duration of the isotropic etching.

At operation S4, the front passivation region 191 may be deposited on the one surface of the crystalline semiconductor substrate 110, and an antireflective region 130 may be formed on the front passivation region 191.

Alternately, a front surface field (FSF) region 171 may be deposited on the front passivation region 191 first and an antireflective region 130 may be formed on the front surface field (FSF) region 171.

As described above, the rounded portion may be formed on the edge portion EP1, the apex portion TP1, and the valley portion VP1 of the pyramidal shaped projection P1 in accordance with an embodiment of the invention. Accordingly, the passivation effect of the front passivation region 191 and the electric field effect of the front surface field (FSF) region 171 may be generated further uniformly so as to further improve the efficiency of the solar cell 1.

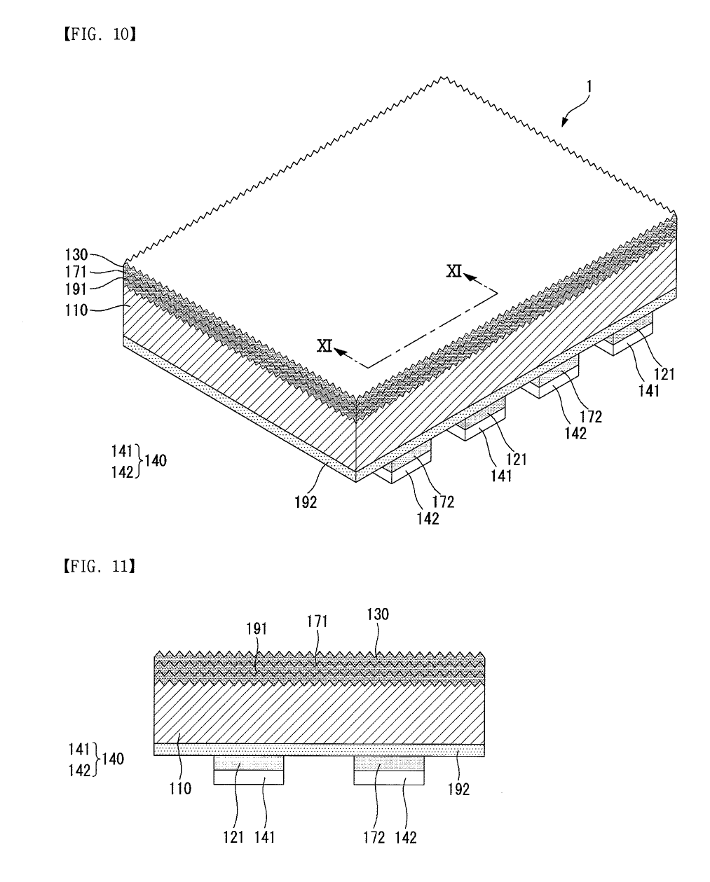

FIGS. 10 and 11 illustrate a solar cell in accordance with another embodiment of the invention.

FIG. 10 is a partial perspective view of a solar cell in accordance with an embodiment of the invention, and FIG. 11 is a cross section view of the solar cell of FIG. 10 taken along line XI to XI.

Referring to FIGS. 10 and 11, the solar cell 1 may include a crystalline semiconductor substrate 110, a front passivation region 191, a front surface field (FSF) region 171, an antireflection region 130, a back passivation region 192, a plurality of first amorphous silicon regions 121, a plurality of second amorphous silicon regions 172, and a plurality of first and second electrodes 141 and 142. The crystalline semiconductor substrate 110 may include an incident surface that may be referred to as a front surface. The front passivation region 191 may be formed on the front surface. The front surface field (FSF) region 171 may be formed on the front passivation region 191. The antireflection region 130 may be formed on the front surface field (FSF) region 171. The back passivation region 192 may be formed on a back surface of the crystalline semiconductor substrate 110. The back surface may be a surface where light does not enter. The back surface may be opposite to the front surface of the crystalline semiconductor substrate 110. The plurality of first amorphous silicon regions 121 may be formed on the back passivation region 192. The plurality of second amorphous silicon regions 172 may be formed on the back passivation region 192 and separated from the plurality of amorphous silicon regions 121. The plurality of first amorphous silicon regions 121 may be referred to as the plurality of emitter regions 121. The second amorphous silicon regions 172 may be referred to as back surface field (BSF) regions 172. The plurality of first electrodes 141 may be formed on the plurality of first amorphous silicon region 121, respectively. The plurality of second electrodes 142 may be formed on the plurality of second amorphous silicon regions 172, respectively.

The solar cell 1 was described as including the antireflection region 130, the front surface field (FSF) region 171, the second amorphous silicon region 172, and the back passivation region 192 in FIGS. 10 and 11, but the antireflection region 130, the front surface field (FSF) region 171, the second amorphous silicon region 172, and the back passivation region 192 may be omitted in accordance with another embodiment of the invention.

When the solar cell 1 includes the antireflection region 130, the front surface field (FSF) region 171, the second amorphous silicon region 172, and the back passivation region 192, the photoelectric effect of the solar cell 1 may be further improved. Accordingly, the solar cell 1 will be described as including the antireflection region 130, the front surface field (FSF) region 171, the second amorphous silicon region 172, and the back passivation region 192, hereinafter.

Constituent elements of the solar cell 1 of FIGS. 10 and 11 are identical to those of FIGS. 1 and 2 except the crystalline semiconductor substrate 110. Therefore, a detailed description thereof will be omitted herein.

Unlike the solar cell shown in FIGS. 1 to 9, a textured surface formed on the incident surface of the crystalline semiconductor substrate 110 shown in FIGS. 10 and 11 may include depressions having a reverse-pyramidal shape.

The depressions may include a rounded edge portion where two adjacent inclination surfaces meet and a rounded lower apex portion where the two adjacent inclination surfaces and another inclination surface meet. The rounded lower apex portion and the rounded edge portion may have a rounded portion.

Since the edge portion and the lower apex portion of the reverse-pyramidal shaped depression have the rounded portion, the front passivation region 191, the front surface field (FSF) field 171, or the antireflection region 130 may be uniformly formed on the lower apex portion of the reverse-pyramidal shaped projections when the front passivation region 191, the front surface field (FSF) region 171 or the antireflection region 130 are formed on the incident surface of the crystalline semiconductor substrate 110.

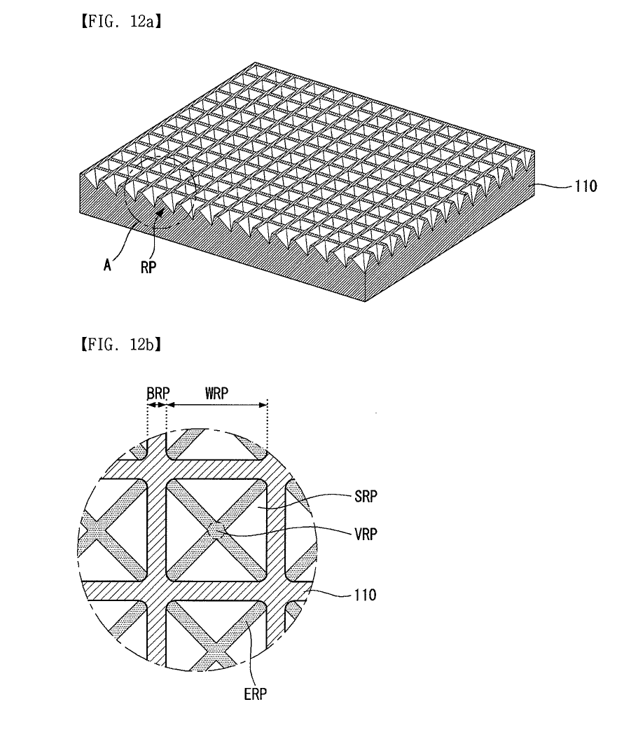

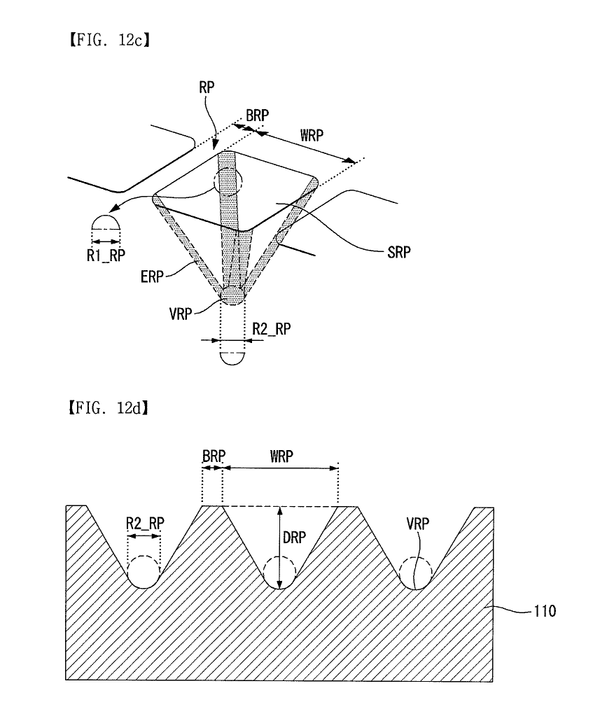

The rounded portion of the edge portion and the apex portion of the reverse-pyramidal shaped depression will be described in detail with reference to FIGS. 12A to 12D.

Unlike the solar cell of FIGS. 10 and 11, the textured surface may be formed on the back surface of the crystalline semiconductor substrate 110 as well as the front surface thereof. In this instance, the back passivation region 192, the plurality of emitter regions 121, the back surface field (BSF) regions 172 and the first and second electrodes 141 and 142, which are formed on the back surface of the crystalline semiconductor substrate 110, may also have a textured surface.

However, when the back surface of the crystalline semiconductor substrate 110 does not include a plurality of depression because the back surface, which is opposite to the incident surface, is not textured, the back passivation region 192, the emitter region 121, and the back surface field (BSF) region 172 may be further uniformly and stably adhered to and formed on the back surface of the crystalline semiconductor substrate 110. Also, the contact resistance between the emitter region 121, the back surface field region 172, and the first and second electrodes 141 and 142 may be reduced.

That is, when the back surface of the crystalline semiconductor substrate 110 does not include a plurality of depressions because the back surface is not a textured surface, the back passivation region 192, a plurality of emitter regions 121, and the back surface field (BSF) region 172 may be formed with an uniform thickness on the back surface of the crystalline semiconductor substrate 110.

Furthermore, when the back surface of the crystalline semiconductor substrate 110 is not a textured surface, the emitter region 121 and the back surface field (BSF) region 172 also does not have a textured surface. Accordingly, the first and second electrodes 141 and 142 may further be stably adhered to the emitter region 121 and the back surface field (BSF) region 172. Accordingly, contact resistance between the emitter region 121 and the back surface field (BSF) region 172 and the first and second electrodes 141 and 142 may be reduced.

Since the front passivation region 191, the front surface field (FSF) region 171, the back passivation region 192, the plurality of first amorphous silicon regions 121, the back passivation region 192, the plurality of second amorphous silicon regions 172, and the plurality of first and second electrodes 141 and 142 were already described in detail with reference to FIGS. 1 and 2, the detailed descriptions thereof will be omitted herein.

Hereinafter, the rounded portion formed on the apex portion of each reverse-pyramidal shaped depression formed on the incident surface of the crystalline semiconductor substrate 110 will be described in detail.

FIGS. 12A to 12D illustrate a plurality of reverse-pyramidal shaped depressions formed on the crystalline semiconductor substrate as shown in FIGS. 10 and 11.

FIG. 12A is a perspective view of a plurality of reverse-pyramidal shaped depressions formed on an incident surface of an crystalline semiconductor substrate 110. FIG. 12B is an enlarged view of a portion A of FIG. 12A. FIG. 12B is a top view of each reverse-pyramidal shaped depression. FIG. 12C is a 3-D view (or a perspective view) of each reverse-pyramidal shaped depression. FIG. 12D is a cross section of each reverse-pyramidal shaped depression.

As illustrated in FIG. 12A, a front surface of the crystalline semiconductor substrate 110 may be an incident surface and may be textured. Accordingly, a plurality of depressions may be formed on the front surface. A back surface of the crystalline semiconductor substrate 110, which is opposite to the front surface, may be not textured. Accordingly, a plurality of depression may be not formed on the back surface.

As illustrated in FIG. 12B, the incident surface of the crystalline semiconductor substrate 110 may include a plurality of reverse-pyramidal shaped depressions having a uniform size, and the plurality of reverse-pyramidal shaped depressions may be uniformly distributed on the incident surface of the crystalline semiconductor substrate 110.

In accordance with an embodiment of the invention, a width of a top surface of each reverse-pyramidal shaped depression may be uniform. Furthermore, a gap between top surfaces of adjacent depressions may be uniform. That is, the plurality of depressions may be formed at a uniform gap or interval.

As illustrated in FIG. 12A to FIG. 12D, a plurality of depressions have the uniform size and are uniformly distributed on the incident surface of the crystalline semiconductor substrate 110 in accordance with an embodiment of the invention. In this instance, a light reflection path may be comparatively extended. Accordingly, the light reflectivity may be reduced so as to increase output current Jsc. As a result, the photoelectric efficiency of the solar cell may be improved.

In the solar cell, at least one of the plurality of reverse-pyramidal shaped depressions RP may include a rounded edge portion ERP where two adjacent inclination surfaces SRP meet and a rounded lower apex portion VRP where the two adjacent inclination surfaces and another inclination surface meet.

When the edge portion ERP and the lower apex portion VRP of the reverse-pyramidal shaped projection have a rounded portion, the front passivation region 191 and the front surface field (FSF) region 171 may be closely adhered to the rounded edge portion ERP and the rounded lower apex portion VRP when the front passivation region 191 and the front surface (FSF) region 171 are formed on the incident surface of the crystalline semiconductor substrate 110.

That is, when a plurality of reverse-pyramidal shaped depressions are formed on the incident surface of the crystalline semiconductor substrate 110, but the rounded portion is not formed on the edge portions ERP and the lower apex portion VRP of the reverse-pyramidal shaped depressions, spaces in the vicinity of the edge portions ERP and the lower apex portion VRP of the reverse-pyramidal shaped depressions will be too narrow. Accordingly, when the front passivation region 191 and the front surface field (FSF) region 171 are deposited, the front passivation region 191 and the front surface field (FSF) region 171 will not be closely adhered to the edge portions ERP and the lower apex portion VRP of the reverse-pyramidal shaped depressions. That is, an empty space will be formed between the front passivation region 191 and the front surface field (FSF) region 171 and the edge portions ERP and the lower apex portions VRP of the reverse-pyramidal shaped depressions. Such an empty space (voids or hollows) may deteriorate the passivation effect and the electric field effect.

When the rounded portions are formed at the edge portions ERP and the lower apex portion VRP of the reverse-pyramidal shaped depressions in accordance with an embodiment of the invention, the front passivation region 191 and the front surface field (FSF) region 171 may be closely adhered to the edge portions ERP and the lower apex portions VRP of the reverse-pyramidal shaped depressions. Accordingly, the rounded portion may increase the passivation effect and the electric field effect.

Furthermore, since the edge portion ERP and the lower apex portion VRP have the rounded portion, the front passivation region 191 and the front surface field (FSF) region 171 may be further uniformly formed on the edge portion ERP and the lower apex portion VRP when the front passivation region 191 and the front surface field (FSF) region 171 are formed on the incident surface of the crystalline semiconductor substrate 110. Accordingly, the rounded portion may improve the passivation effect that electric charges such as electrons are dissipated by a dangling bond generated at or in the vicinity of the incident surface of the crystalline semiconductor substrate 110. Furthermore, the rounded portion may further improve the electric field effect that prevent electric charge loss that may be caused by electron and hole recombination.

Therefore, the passivation effect and the electric field effect of the front passivation region 191 and the front surface field (FSF) region 171 may be improved at or in the vicinity of the incident surface of the crystalline semiconductor substrate 110. As a result, the photoelectric efficiency of the solar cell may be further improved.

A diameter R1_RP and R2_RP of each rounded portion of the rounded edge portion and the rounded lower apex portion VRP of the reverse-pyramidal shaped depression may be greater than about 5 nm and smaller than 15 nm. Such a size of the rounded portion may be determined by controlling etching duration of an isotropic etching after forming the pyramidal shaped depression RP through an anisotropic etching.

The diameters R1_RP and R2_RP of the rounded portion may be controlled to be greater than about 5 nm in order to closely adhere the front passivation region 191 and the front surface field (FSF) region 171 to the edge portions ERP of the inclination surface and the lower apex portions VRP, and in order to uniformly form the front passivation region 191 and the front surface field (FSF) region 171 on the edge portions ERP of the inclination surface and the lower apex portions VRP. The diameters R1_RP and R2_RP of the rounded portion may be controlled to be smaller than about 15 nm in order to minimize the reflectivity of incident light. When the diameters R1_RP and R2_RP of the rounded portion are greater than about 15 nm, the uniformity of the front passivation region 191 and the front surface field (FSF) region 171 formed on the crystalline semiconductor substrate 110 may be further improved, but the light reflectivity also may be increased.

A space (or area) BRP between two adjacent bases of reverse-pyramidal shaped depressions may be controlled to be equal to or less than about 1 μm in width.

That is, optionally, no space BRP between the bases of reverse-pyramidal shaped depressions may be formed because the inclination surfaces of reverse-pyramidal shaped depressions contact to each other. The space BRP may also be controlled to be less than about 10 μm in width. Nevertheless, the space BRP between the bases of the reverse-pyramidal shaped depressions may be minimized to be less than about 1 μm in width in order to minimize the reflectivity of light reflected by a surface formed by the space BRP between the bases of reverse-pyramidal shaped depressions.

The space BRP between the bases of the reverse-pyramidal shaped depressions may be determined by controlling an etching duration or by controlling a width of a mask formed on the crystalline semiconductor substrate 110 while etching the crystalline semiconductor substrate 110 in order to form the depressions.

A ratio of a depth DRP with respect to a width WRP in a base of each of the plurality of reverse-pyramidal shaped depressions RP may be controlled to be about 1:1 to 1.5.

According to the ratio of the depth DRP with respect to the width WRP of the reverse-pyramidal shaped depressions RP, an angle formed by a base and an inclination surface SRP of the reverse-pyramidal shaped depression RP may be determined or selected. When the ratio of the depth DRP with respect to the width WRP is controlled to be greater than about 1:1, an angle formed by the base and the inclination surface SRP may properly incline. Accordingly, the light reflectivity may be reduced to a minimum, and the photoelectric efficiency may be optimized.

When the ratio of the depth DRP with respect to the width WRP is controlled to be smaller than about 1:1.5, the angle formed by the base and the inclination surface SRP may become optimized. The lower apex portion VRP of the reverse-pyramidal shaped depression may be prevented from excessively inclining so as to prevent a space of the lower apex portion VRP from becoming too narrow. Accordingly, the front passivation region 191, the front surface field (FSF) region 171, and the antireflection region 130 may be further closely adhered to the crystalline semiconductor substrate 110 when the front passivation region 191, the front surface field (FSF) region 171, and the antireflection region 130 are formed on the crystalline semiconductor substrate 110.

The width WRP of the base of each reverse-pyramidal shaped depression RP may be greater than about 0.5 μm and smaller than about 10 μm. The depth of each reverse-pyramidal shaped depression RP may be greater than about 0.5 μm and smaller than about 15 μm.

As the width WRP of the base becomes greater, the depth DRP of each reverse-pyramidal shaped depression RP also becomes deeper due to the characteristics of the etching process. Furthermore, as the width WRP of the base becomes smaller, the depth DRP of each reverse-pyramidal shaped depression RP also becomes shallower due to the characteristics of the etching process. Therefore, an overall size of each reverse-pyramidal shaped depression RP may be determined based on a size of a width of a base of each reverse-pyramidal shaped depression RP.

Accordingly, the width of the base may be controlled to be greater than about 5 μm and smaller than about 10 μm, and the depth DRP of each reverse-pyramidal shaped depression RP may be controlled to be greater than about 0.5 μm and greater than about 15 μm in order to obtain an optimal size of each reverse-pyramidal shaped depression RP so that an optimal light path for incident light may be obtained. Therefore, the photoelectric efficiency of the solar cell may be improved. That is, the incident light may enter and reflect several times through incident surfaces SRP of the plurality of reverse-pyramidal shaped depressions. In this instance, an optical path of incident light may be extended so as that an increased amount of light can enter the crystalline semiconductor substrate 110. Accordingly, the photoelectric efficiency of the solar cell may be improved.

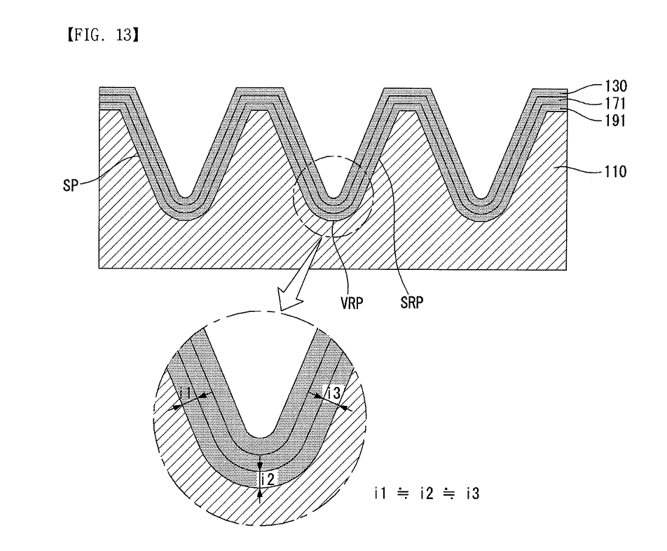

FIG. 13 is a diagram for describing effects provided due to a curved space at a lower apex portion of a reverse-pyramidal shaped depression of FIG. 12.

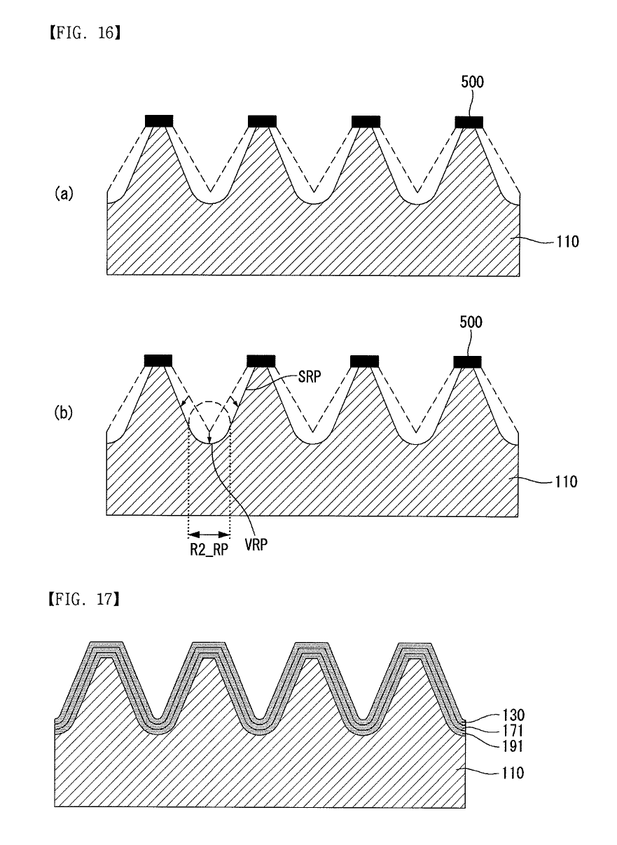

When the lower apex portion VRP of each reverse-pyramidal shaped depression RP has a rounded portion R2_RP (see FIG. 16) as illustrated in FIG. 13, the front passivation region 191 is formed uniformly on the inclination surface SRP and the lower apex portion VRP of each reverse-pyramidal shaped depression RP when the front passivation region 191 is formed on the reverse-pyramidal shaped depressions RP.

When the lower apex portion VRP of each reverse-pyramidal shaped depression RP has a sharp angle without having the curved space R2_RP, the front passivation region 191 may be not uniformly formed on the lower apex portion VRP. In this instance, the front passivation region 191 may be not closely adhered to the lower apex portion VRP and separated from the lower apex portion VRP.

When the front passivation region 191 is separated from the lower apex portion VRP of each reverse-pyramidal shaped depression RP, the passivation effect may be comparatively deteriorated at the inclination surface SRP and the lower apex portion VRP of each reverse-pyramidal shaped depression RP. Accordingly, electric charges may become extinct due to the deterioration of the passivation effect at the inclination surface of SRP and the lower apex portion VRP of each reverse-pyramidal shaped depression RP. The photoelectric effect of the solar cell also may be deteriorated.

When the front surface field (FSF) region 171 is further formed on the front passivation region 191 as illustrated in FIGS. 10 and 11 without forming a curved space at the lower apex portion VRP of each reverse-pyramidal shaped depression RP, the front surface field (FSF) region 171 also may be separated from the lower apex portion VRP. Accordingly, the electric field effect of the front surface field (FSF) region 171 may be deteriorated. In this instance, the photoelectric efficiency of the solar cell also may be deteriorated because electrons and holes may be easily recombined together at the lower apex portion VRP of each reverse-pyramidal shaped depression RP.

When the rounded portion is formed on the lower apex portion VRP and the edge portion ERP of the inclination surface of each reverse-pyramidal shaped depression RP, the front passivation region 191 and the front surface field (FSF) region 171 may be closely adhered to the lower apex portion VRP of each reverse-pyramidal shaped depression RP and the edge portion of the inclination surface SRP as illustrated in FIG. 13. Furthermore, in this instance, the front passivation region 191 and the front surface field (FSF) region 171 may be uniformly formed on the lower apex portion VRP of the inclination surface SRP of each reverse-pyramidal shaped depression RP. Accordingly, the passivation effect and the electric field effect may not be deteriorated. The passivation effect and the electric field effect may be uniformly generated. Therefore, the photoelectric efficiency of the solar cell may be further improved.

When the antireflection region 130 is formed on the front surface field (FSF) region 171 as illustrated in FIG. 13, the effect of the antireflection region 130 may be optimally obtained or demonstrated.

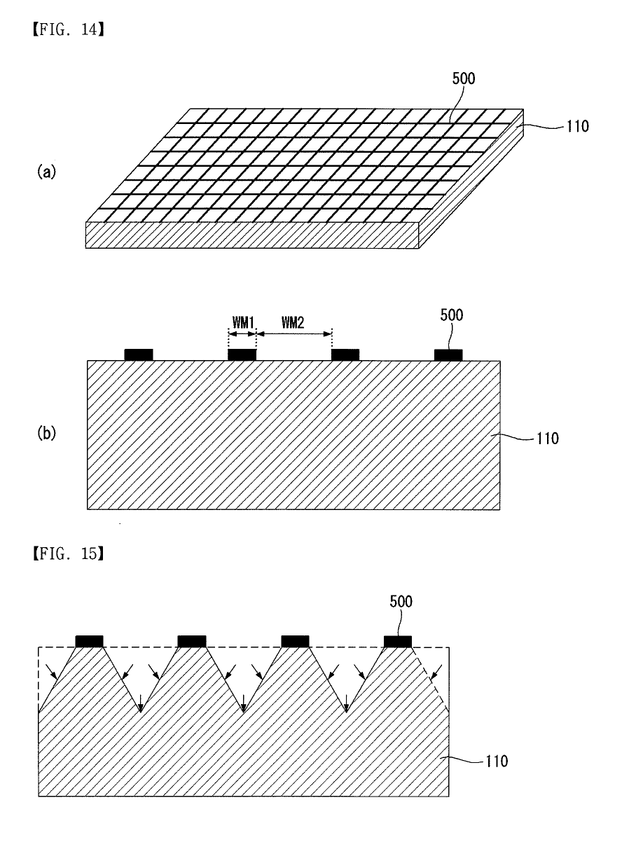

FIGS. 14 to 17 illustrate a method for forming a curved space at an edge portion ERP of an inclination surface SRP of a lower apex portion VRP of each reverse-pyramidal shaped depression RP.

As illustrated in a diagram (a) of FIG. 14, a mesh shaped etching mask 500 is formed on an incident surface of a crystalline semiconductor substrate 110 in order to form a plurality of depressions. A diagram (b) of FIG. 14 is a side view of the etching mask 500 formed on the incident surface of the crystalline semiconductor substrate 110. A space BRP between adjacent bases of reverse-pyramidal shaped depressions RP may be determined according to a width of the etching mask 500 and etching duration. Furthermore, a width WRP of a base of each reverse-pyramidal shaped depression RP may be determined according to a space WM2 in the etching mask 500 and an etching time.

In order to form the space BRP between bases of reverse-pyramidal shaped depressions RP to be smaller than about 1 μm, the width WM1 of the etching mask 500 may be formed to be greater than about 0.8 μm to about 1.2 μm in consideration of an etching time. In order to form the width WRP of the base of each reverse-pyramidal shaped depression RP to be greater than about 0.5 μm and smaller than about 10 μm, the width WM2 of the etching mask 500 may be formed to be greater than about 0.5 μm and smaller than about 10 μm in consideration of the etching duration.

After forming the etching mask 500 on the incident surface of the crystalline semiconductor substrate 110, anisotropic etching is performed at first. The incident surface of the crystalline semiconductor substrate 110 is etched inwardly and a plurality of reverse-pyramidal shaped depresses are formed on the incident surface of the crystalline semiconductor substrate 110 as shown in FIG. 15. As described above, the plurality of depressions have a uniform size because of the etching mask 500.

The anisotropic etching may be performed until the space BRP between adjacent bases of reverse-pyramidal shaped depressions RP becomes about 1 μm. By the anisotropic etching, reverse-pyramidal shaped depressions are formed. However, curved spaces are not formed at the lower apex portion VRP of each reverse-pyramidal shaped depression RP and the edge portion ERP of the inclination surface SRP as illustrated. By the anisotropic etching, an angle formed by the base and the inclination surface SRP of each reverse-pyramidal shaped depression RP may come to be about 54.7°.

After performing the anisotropic etching, isotropic etching may be performed. As a result, the depressions formed on the incident surface of the crystalline semiconductor substrate 110 may be further etched. As illustrated in diagrams (a) and (b) of FIG. 16, a bottom surface of the etching mask 500 is also etched, as well as the insides of the depressions. By the isotropic etching, a space BRP between adjacent bases of reverse-pyramidal shaped depressions RP may be formed to be smaller than about 1 μm. Furthermore, a rounded portion may be formed at the lower apex portion VRP of each reverse-pyramidal shaped depression RP and the edge portion ERP of the inclination surface SRP.

The etching duration of performing the isotropic etching may be controlled to control a diameter of the curved space formed at the lower apex portion VRP of each reverse-pyramidal shaped depression RP and the edge portion ERP of the inclination surface SRP to be greater than about 5 nm and smaller than about 15 nm.

FIG. 16 illustrates that the isotropic etching is performed while keeping the etching mask 500 on the incident surface of the crystalline semiconductor substrate 110. Unlike FIG. 16, the isotropic etching may be performed after removing the etching mask 500 in other embodiments of the invention.

As illustrated in FIG. 17, the front passivation region 191, the front surface field (FSF) region 171, and the antireflection region 130 may be sequentially deposited and formed on the incident surface of the crystalline semiconductor substrate 110, which includes a plurality of reverse-pyramidal shaped depressions RP.

When the front passivation region 191, the front surface field (FSF) region 171, and the antireflection region 130 are sequentially deposited and formed on the incident surface of the crystalline semiconductor substrate 110, the front passivation region 191, and the front surface field (FSF) region 171, and the antireflection region 130 may be further closely adhered to the lower apex portion VRP of the reverse-pyramidal shaped depression RP and the edge portion ERP of the inclination surface SRP because of the curved spaces formed on the lower apex portion VRP of each reverse-pyramidal shaped depression RP and the edge portion ERP of the inclination surface SRP.

Furthermore, the rounded portions functions to uniformly form the front passivation region 191, and the front surface field (FSF) region 171, and the antireflection region 130 on the lower apex portion VRP of the reverse-pyramidal shaped depression RP and the inclination surface SRP

As described above, the rounded portions are formed at the lower apex portion VRP of each reverse-pyramidal shaped depression RP and the edge portion ERP of the inclination surface SRP in the solar cell in accordance with an embodiment of the invention. Accordingly, the passivation effect of the front passivation region 191 and the electric field effect of the front surface field (FSF) region 171 may become further uniformly generated so as to improve the photoelectric efficiency of the solar cell.

The foregoing example embodiments and aspects of the invention are merely examples and are not to be construed as limiting the invention. The teaching can be readily applied to other types of apparatuses. Also, the description of the example embodiments of the invention is intended to be illustrative, and not to limit the scope of the claims, and many alternatives, modifications, and variations will be apparent to those skilled in the art.

What is claimed is:

1. A solar cell comprising:
a crystalline semiconductor substrate of a first conductivity type, the crystalline semiconductor substrate having a plurality of pyramidal-shaped projections or a plurality of reverse-pyramidal shape depressions on at least one surface thereof;
a first amorphous silicon region positioned on the crystalline semiconductor substrate and having a second conductivity type opposite the first conductivity type;
a first electrode positioned on the first amorphous silicon region; and
a second electrode positioned on the substrate,
wherein at least one pyramidal-shaped projection or at least one reverse-pyramidal shape depression includes two adjacent inclination surfaces, and a rounded edge portion where the two adjacent inclination surfaces meet.

2. The solar cell of claim 1, wherein the at least one pyramidal-shaped projection or the at least one reverse-pyramidal shape depression further includes another inclination surface and a rounded apex portion where the two adjacent inclination surfaces and the another inclination surface meet.

3. The solar cell of claim 2, wherein the rounded edge portion and the rounded apex portion have diameters of about 5 nm to 15 nm, respectively.

4. The solar cell of claim 1, wherein base portions of the plurality of pyramidal-shaped projections has a width of about 5 μm to 15 μm.

5. The solar cell of claim 2, wherein an angle formed by one of the two adjacent inclination surfaces and a base portion of the at least one pyramidal-shaped projection is equal to or more than about 45° and less than about 54.7°

6. The solar cell of claim 1, further comprising a valley portion between two adjacent pyramidal-shaped projections, wherein the valley portion has a rounded portion.

7. The solar cell of claim 1, wherein the crystalline semiconductor substrate has an inclination surface and a back surface that is opposite the inclination surface, and the back surface lacks the plurality of pyramidal-shaped projections or the plurality of the reverse-pyramidal shape depressions.

8. The solar cell of claim 1, wherein the crystalline semiconductor substrate has an inclination surface, and the crystalline semiconductor substrate further comprises a front passivation region positioned on the inclination surface and containing an amorphous silicon material.

9. The solar cell of claim 8, wherein the front passivation region has a uniform thickness at the rounded edge portion or the rounded apex portion.

10. The solar cell of claim 1, wherein the crystalline semiconductor substrate has an inclination surface, and the plurality of pyramidal-shaped projections or the plurality of reverse-pyramidal-shape depressions are on the inclination surface.

11. The solar cell of claim 1, wherein a ratio of a depth with respect to a width in a base of each of the plurality of reverse-pyramidal shape depressions is 1:1 to 1.5.

12. The solar cell of claim 1, wherein a width of a base of each of the plurality of reverse-pyramidal shape depressions is about 0.5 μm to 10 μm.

13. The solar cell of claim 1, wherein a depth of each of the plurality of reverse-pyramidal shape depressions is about 0.5 μm to 15 μm.

14. The solar cell of claim 1, wherein a space between bases of two adjacent reverse-pyramidal shape depressions is equal to or less than lgm.

15. The solar cell of claim 1, wherein the crystalline semiconductor substrate has an inclination surface and a back surface that is opposite the inclination surface, and the first amorphous region is positioned on the back surface.

16. The solar cell of claim 15, further comprising a second amorphous silicon region positioned on the crystalline semiconductor substrate and having the first conductivity type, and the second amorphous region is positioned on the back surface.
